(19) United States
(12) Patent Application Publication
(10) Pub. No.: US 2026/0107585 A1
(43) Pub. Date: Apr. 16, 2026

(54) SENSOR PACKAGE AND MANUFACTURING METHOD THEREOF

(71) Applicant: OMNIVISION TECHNOLOGIES, INC., Santa Clara, CA (US)

(72) Inventors: Yen Yu Liu, Hsinchu City (TW); Chien Liang Liao, Hsinchu City (TW); Larry Kinsman, Santa Clara, CA (US)

(73) Assignee: OMNIVISION TECHNOLOGIES, INC., Santa Clara, CA (US)

(21) Appl. No.: 18/916,653

(22) Filed: Oct. 15, 2024

(51) Int. Cl. H01L 27/146

(52) U.S. Cl. CPC H10F 39/026; H10F 39/018; H10F 39/024; H10F 39/8057; H10F 39/809; H10F 39/811

(57) ABSTRACT

A sensor package includes a sensor die, an insulating layer covering the second side of the sensor die, a cover layer, a dielectric dam between the cover layer and the sensor die, a circuit substrate coupled to the sensor die, and an encapsulant laterally covering the cover layer, the dielectric dam, and the insulating layer. The sensor die includes opposing first and second sides, a sensing area at the first side, conductive terminals at the second side and coupling the sensor die to the circuit substrate. The insulating layer exposes the first side of the sensor die. The cover layer is disposed above the first side of the sensor die and covers the sensing area, the dielectric dam is disposed outside the sensing area, and the encapsulant extends into a gap between the circuit substrate and the insulating layer to surround the conductive terminals.

### BACKGROUND

### Technical Field

The present disclosure generally relates to a package and a manufacturing method thereof and, more specifically, to a sensor package and a manufacturing method thereof.

### Description of Related Art

Image sensors utilize an array of pixels to capture an optical image. There are a variety of techniques to package the image sensors. In accordance with a rapid increase in demand for miniaturized sensor packages, implementation of a sensor package having a compact size has been demanded. For example, a sensor package includes a sensor die covered by an insulating layer, an optical glass is disposed over the sensor die for permitting the incident light to be received by the sensor die, and the optical glass is attached to the sensor die through a dam encircling a sensing area of the sensor die.

Although the currently used packaging technique is satisfactory, it includes drawbacks. For example, the optical glass has a coefficient of thermal expansion (CTE) different from that of the dam and the sensor die, thereby easily resulting in delamination between the optical glass and the dam due to thermal stress generated by the deposition processes. The CTE mismatch may cause reliability concerns. By selecting the material of the optical glass having a certain range of CTE may reduce the risk of delamination; however, the material selection of the optical glass is highly limited. Therefore, in light of the above described problem, a need exists for improved sensor package and manufacturing method thereof.

### SUMMARY

In accordance with some embodiments, a sensor package includes a sensor die, an insulating layer, a cover layer, a dielectric dam between the cover layer and the sensor die, a circuit substrate coupled to the sensor die, and an encapsulant laterally covering the cover layer, the dielectric dam, and the insulating layer. The sensor die includes a first side, a second side opposite to the first side, a sensing area at the first side, conductive terminals at the second side and coupling the sensor die to the circuit substrate. The insulating layer covers the second side of the sensor die and exposes the first side of the sensor die. The cover layer is disposed above the first side of the sensor die and covers the sensing area, the dielectric dam is disposed outside the sensing area, and the encapsulant extends into a gap between the circuit substrate and the insulating layer to surround the conductive terminals.

In accordance with some embodiments, a manufacturing method of a sensor package includes: covering a sensor die with an insulating layer, where the sensor die includes a first side exposed by the insulating layer, a second side opposite to the first side, and a sensing area at the first side; disposing a cover layer over the first side of the sensor die with a dielectric dam interposed between the sensor die and the cover layer, where the dielectric dam is formed outside the sensing area; coupling the sensor die to a circuit substrate through conductive terminals formed at the second side of the sensor die; forming an encapsulant on the circuit substrate to cover the cover layer, the dielectric dam, and the sensor die, wherein the encapsulant extends into a gap between the circuit substrate and the insulating layer to surround the conductive terminals.

In accordance with some embodiments, a sensor package includes a sensor die, an insulating layer, a cover layer, a dielectric dam interposed between the cover layer and the sensor die, a circuit substrate coupled to the sensor die, and an encapsulant laterally covering the cover layer, the dielectric dam, and the insulating layer. The sensor die includes a semiconductor substrate, a sensing area disposed on a front side of the semiconductor substrate, a redistribution layer conformally overlying a backside of the semiconductor substrate, and conductive terminals connected to the redistribution layer, where the backside of the semiconductor substrate includes an irregular cross-sectional profile formed by using a temporary carrier as a support. The insulating layer covers the redistribution layer and exposes the sensing area, where the insulating layer is formed by using the temporary carrier as the support. The cover layer is disposed above the sensing area of the sensor die, where a difference of coefficients of thermal expansion of the temporary carrier and the semiconductor substrate is less than a difference of coefficients of thermal expansion of the cover layer and the semiconductor substrate. The dielectric dam is disposed outside the sensing area, the circuit substrate is coupled to the sensor die through the conductive terminals, and each of the conductive terminals includes a first portion inserted into the insulating layer and a second portion connecting the first portion to the circuit substrate and laterally covered by the encapsulant.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view illustrating a sensor package, in accordance with some embodiments.

FIGS. 2A-2H are schematic cross-sectional views illustrating a sensor package at various steps of fabrication, in accordance with some embodiments.

FIGS. 3A-3E are schematic cross-sectional views illustrating a sensor package at various steps of fabrication, in accordance with some embodiments.

FIGS. 4A-4D are schematic cross-sectional views illustrating a sensor package at various steps of fabrication, in accordance with some embodiments.

### DESCRIPTION OF THE EMBODIMENTS

Embodiments of a sensor package and a manufacturing method thereof are described herein. In particular, the sensor package includes a sensor die including a sensing area at one side and conductive terminals at the opposing side, a cover layer disposed over the sensing area of the sensor die and attached to the sensor die through a dielectric dam, a circuit substrate coupled to the conductive terminals of the sensor die, an encapsulant disposed on the circuit substrate and laterally covering the sensor die, the dielectric dam, and the cover layer. By bonding a temporary carrier having low CTE to the semiconductor wafer when processing the semiconductor wafer and forming the insulating layer and de-bonding the temporary carrier from the sensor die before mounting the cover layer onto the sensor die, the effects from harmful stress caused by CTE mismatch among the sensor die, the insulating layer, and the cover layer may be prevented. The temporary carrier may be de-bonded and replaced with the cover layer tailored for particular optical properties as demands. In this manner, the selection of the material of the cover layer and the thickness of the cover layer may not be limited due to processes of the fabrication of sensor package, thereby providing more flexible design to suit different product requirements.

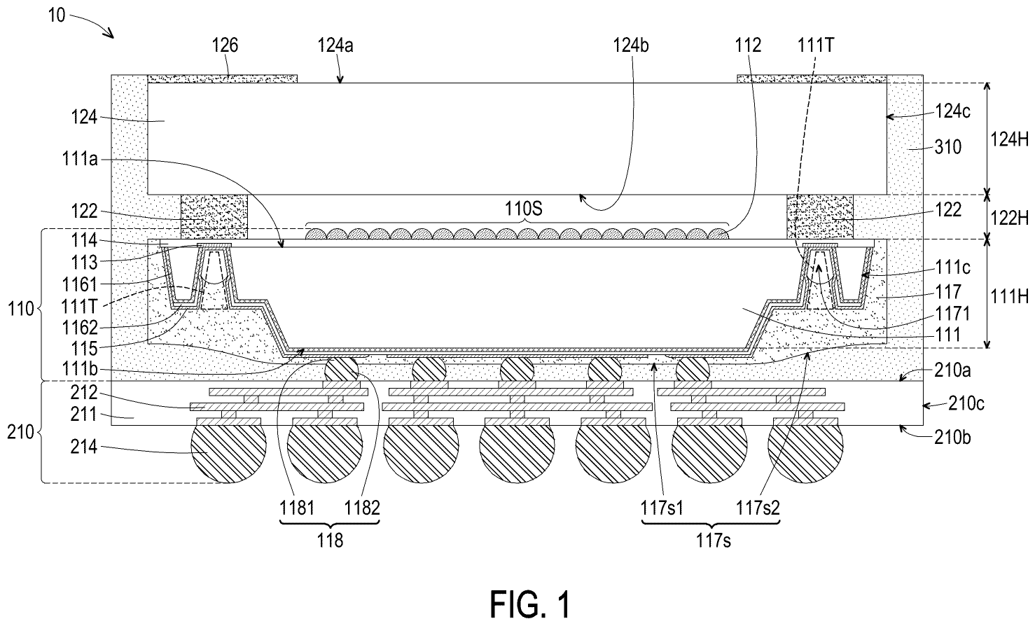

FIG. 1 is a schematic cross-sectional view illustrating a sensor package, in accordance with some embodiments. Referring to FIG. 1, a sensor package 10 may include a sensor die 110, a cover layer 124 disposed over the sensor die 110, a dielectric dam 122 interposed between the cover layer 124 and the sensor die 110, a light-shielding layer 126 disposed on the cover layer 124 and directly over the dielectric dam 122, a circuit substrate 210 underlying and electrically coupled to the sensor die 110, and an encapsulant 310 disposed on the circuit substrate 210 and covering the sensor die 110, the dielectric dam 122, the cover layer 124, and the light-shielding layer 126.

The sensor die 110 may be a complementary metal oxide semiconductor (CMOS) image sensor die; although other types of sensor dies may be used in implementing the disclosure. For example, the sensor die 110 includes a semiconductor substrate 111 including a first side (or a front side) 111a, a second side (or a backside) 111b opposite to the first side 111a, and an outer sidewall 111c connected to the first side 111a and the second side 111b. The sensor die 110 may include a sensing area 110S formed in/on the first side 111a of the semiconductor substrate 111. For example, a plurality of pixels 112 is arranged in a two-dimensional array and disposed within the sensing area 110S, and the sensing area 110S may be referred to as a pixel array region of the sensor die 110. The sensor die 110 may include contact pads 113 formed at the first side 111a and surrounding the sensing area 110S, and a dielectric layer 114 covering the contact pads 113 and separating the contact pads 113 from the dielectric dam 122.

With continued reference to FIG. 1, the sensor die 110 may include one or more redistribution layer(s) (RDL) 115 formed over the second side 111b of the semiconductor substrate 111 and connected to the contact pads 113. In some embodiments, the RDL 115 extends to cover the outer sidewall 111c of the semiconductor substrate 111. The RDL 115 may include signal generation circuitry, signal processing circuitry, row and column selection circuitry, and/or any circuitry associated with sampling and readout of the array of the pixels 112. In some embodiments, the second side 111b of the semiconductor substrate 111 has an irregular profile as shown in the cross-sectional view, where the through holes 111T passing through the semiconductor substrate 111 may cause the irregular profile, and the RDL 115 may be conformally disposed over the irregular profile of the semiconductor substrate 111. The through holes 111T may at least partially expose the contact pads 113, and the RDL 115 disposed in the through holes 111T may be in direct contact with the contact pads 113.

In some embodiments, the sensor die 110 includes an oxide layer 1161 conformally overlying the second side 111b and the outer sidewall 111c of the semiconductor substrate 111. The sensor die may include a buffer layer 1162 partially (or fully) overlying the oxide layer 1161, where the buffer layer 1162 may be interposed between the oxide layer 1161 and the RDL 115. The contact pads 113 may be exposed by the oxide layer 1161, and the RDL 115 formed over the oxide layer 1161 may be in physical contact with the contact pads 113. It should be noted that the cross-sectional profile of the semiconductor substrate 111 and the arrangements of the RDL 115, the oxide layer 1161, and the buffer layer 1162 shown in FIG. 1 are merely examples and may be adjusted depending on product and circuit requirements.

With continued reference to FIG. 1, an insulating layer 117 may cover the backside and the sidewall of the sensor die 110. For example, the insulating layer 117 is formed over the second side 111b and the outer sidewall 111c of the semiconductor substrate 111 to cover the RDL 115. In some embodiments where the second side 111b of the semiconductor substrate 111 has the irregular cross-sectional profile, the insulating layer 117 formed over the backside of the sensor die 110 includes a non-planar surface 117s. For example, the non-planar surface 117s includes a first section 117s1 directly underneath the sensing area 110S and a second section 117s2 connected to the first section 117s1 and directly underneath the dielectric dam 122, where the second section 117s2 may be a curved surface (e.g., a concave-down surface) due to the formation of the through holes 111T.

In some embodiments, blank areas 1171 are formed in the insulating layer 117 and corresponding to the through holes 111T. For example, each of the blank areas 1171 is between the insulating layer 117 and the section of the RDL 115 directly below the respective contact pad 113 to ensure that the insulating layer 117 is spatially separated from the respective contact pad 113, and the contact pads 113 are not affected by thermal expansion and contraction of the insulating layer 117 during the operation of the sensor package 10. The sensor die 110 may include conductive terminals 118 formed over the second side 111b of the semiconductor substrate 111 and electrically coupled to the RDL 115. For example, the conductive terminals 118 are formed in the openings of the first section 117s1 of the insulating layer 117 to be in contact with the RDL 115. The sensor die 110 may be electrically coupled to the circuit substrate 210 through the conductive terminals 118.

With continued reference to FIG. 1, the dielectric dam 122 may be formed on the dielectric layer 114 of the sensor die 110 to surround the sensing area 110S of the sensor die 110. For example, the dielectric dam 122 is directly over the contact pads 113. The dielectric dam 122 may serve as a support to spatially and vertically separate the cover layer 124 from the pixels 112. The dielectric dam 122 may have a sufficient height 122H to eliminate pixel defects such as blemish defects. The dielectric dam 122 may spatially and laterally separate the sensing area 110S from the encapsulant 310. The material and the size of the dielectric dam 122 may be selected based on the optical and process requirements of the sensor package 10.

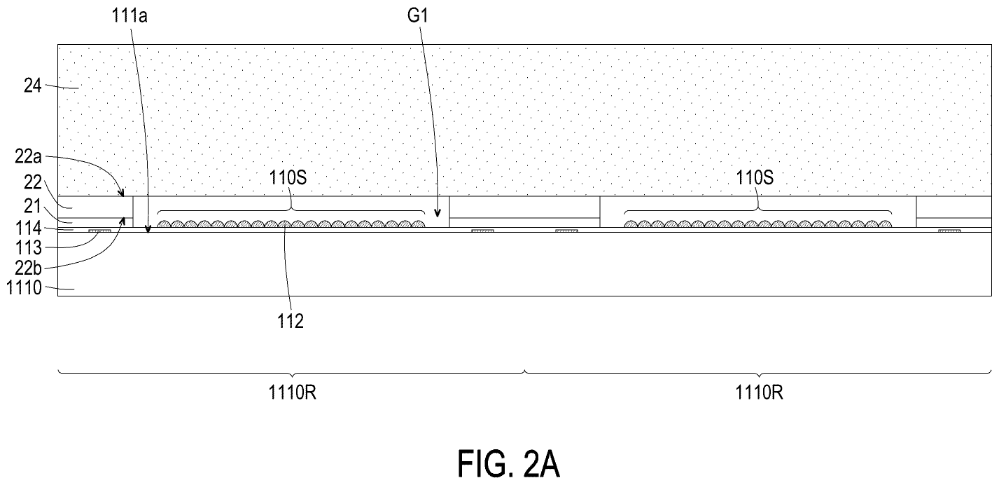

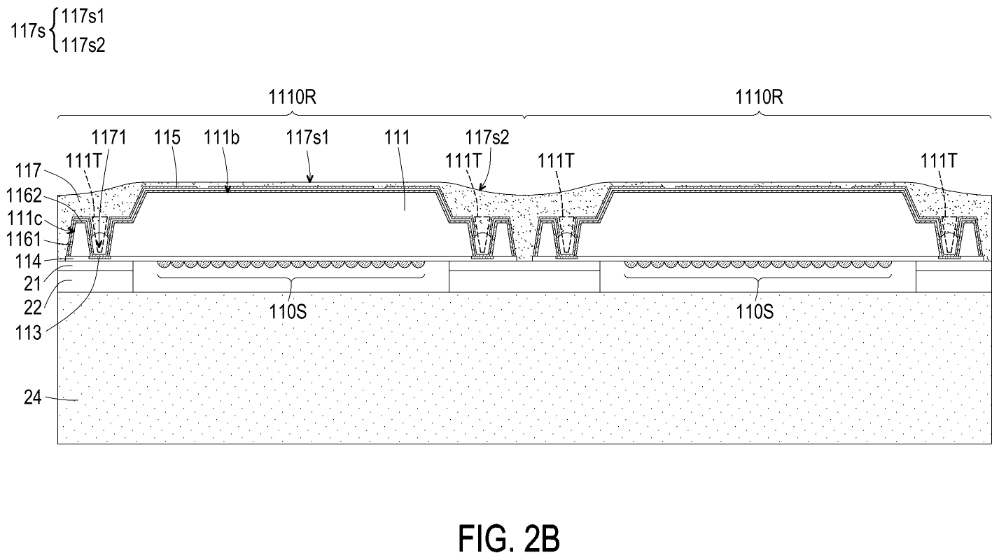

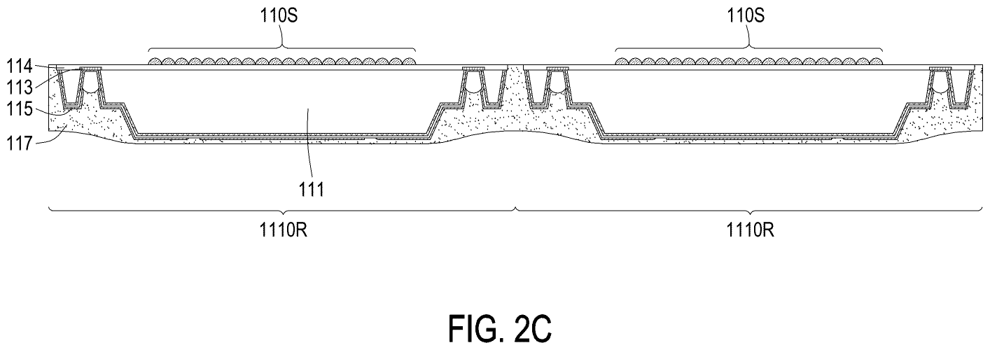

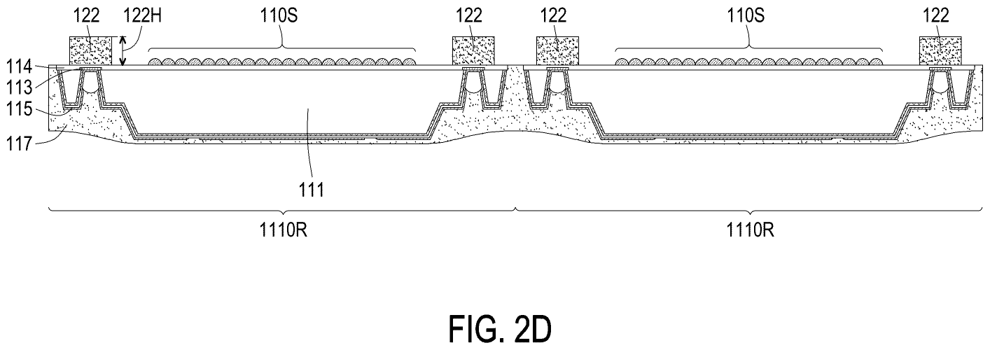

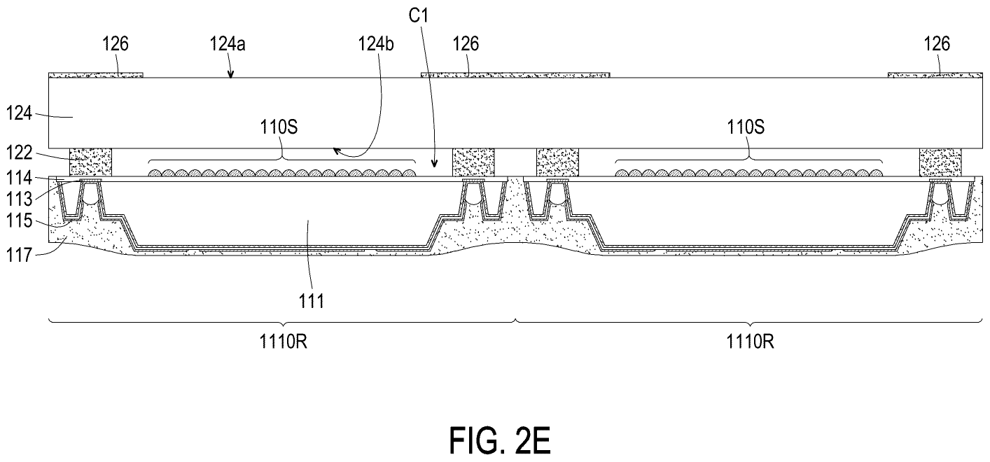

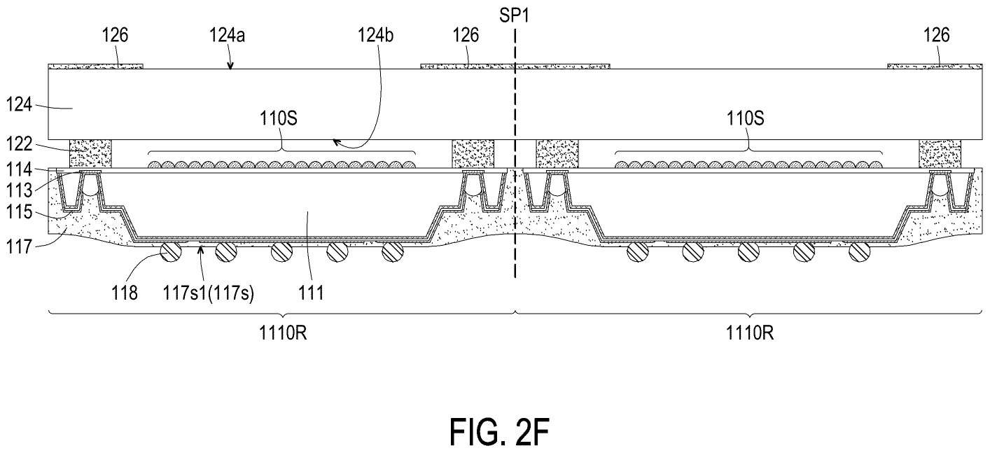

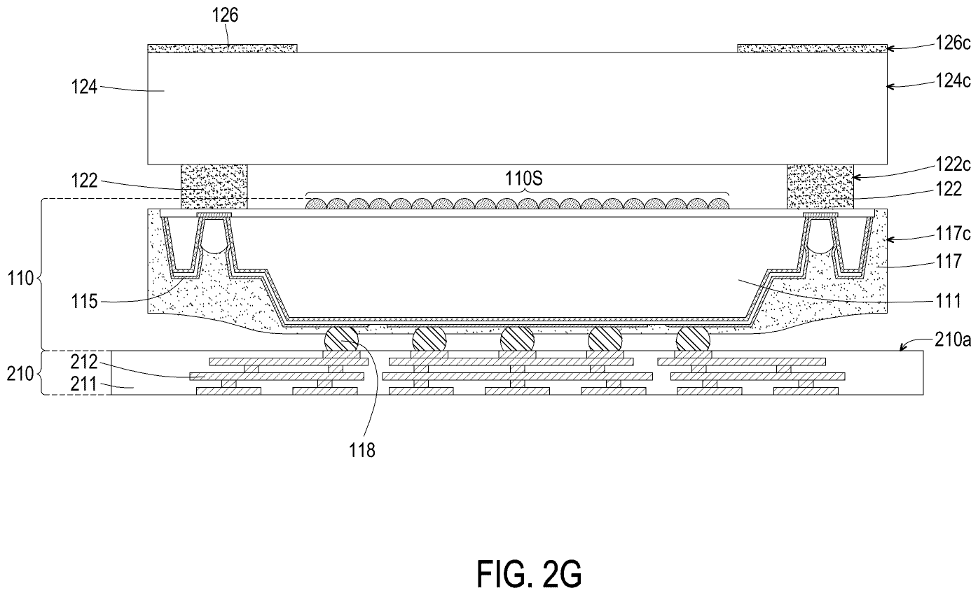

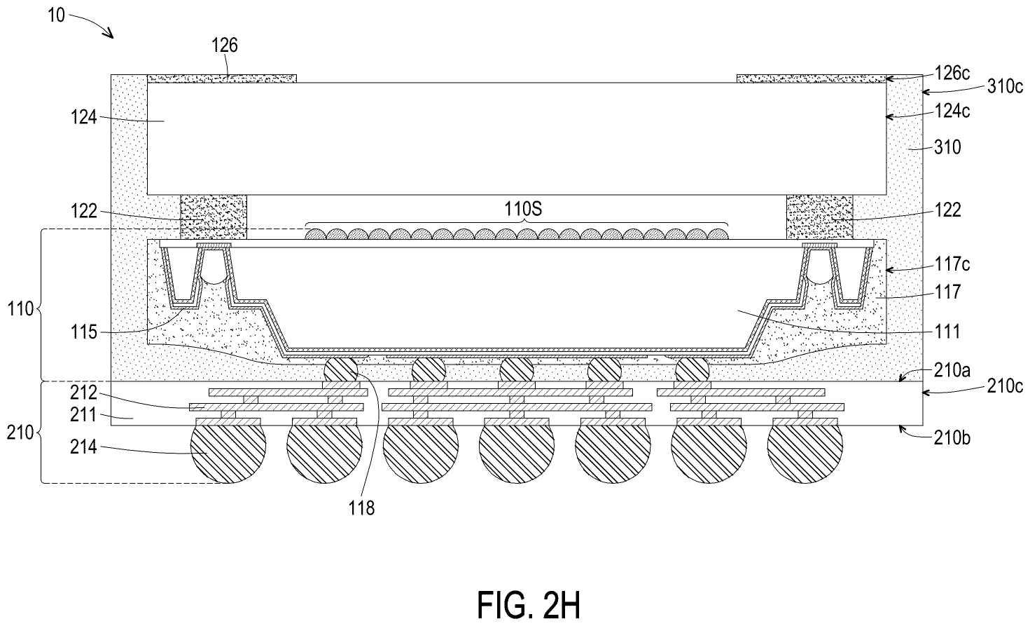

With continued reference to FIG. 1, the cover layer 124 may be disposed on the dielectric dam 122 and cover the sensing area 110S of the sensor die 110. The cover layer 124 may include a first side 124a, a second side 124b opposite to the first side 124a and facing the sensor die 110, and a sidewall 124c connected to the first side 124a and the second side 124b. For example, the material of the cover layer 124 has a CTE greater than the CTE of the semiconductor substrate 111. The present disclosure provides novel manufacturing methods for forming the sensor package 10 as will be described later in accompanying with FIGS. 2A-4D, where the cover layer 124 may have a higher CTE that excludes the sensor package 10 from being negatively affected by the CTE mismatch. The lateral dimension of the cover layer 124 may be selected to mitigate the risk of optical flare. In some embodiments, the thickness of the cover layer 124 is relatively thin to meet the product requirements. For example, the maximum thickness 124H of the cover layer 124 is less than the maximum thickness 111H of the semiconductor substrate 111.

With continued reference to FIG. 1, the light-shielding layer 126 may be disposed on the first side 124a of the cover layer 124. For example, the light-shielding layer 126 disposed on the periphery of the cover layer 124 and directly over the dielectric dam 122. The configuration of the light-shielding layer 126 may help to reduce the optical flare caused by the reflection of the incident light. The light-shielding layer 126 may have a different configuration than shown. For example, the light-shielding layer 126 is disposed on the second side 124b of the cover layer 124 or may be disposed on both of the first side 124a and the second side 124b of the cover layer 124. The encapsulant 310 may be disposed on the circuit substrate 210 and laterally cover the light-shielding layer 126, the cover layer 124, the dielectric dam 122, and the insulating layer 117. In some embodiments, the encapsulant 310 extends into the gap between the non-planar surface 117s of the insulating layer 117 and the circuit substrate 210 to surround the conductive terminals 118. For example, the respective conductive terminal 118 includes a first portion 1181 inserted into the insulating layer 117 to be in contact with the RDL 115 and a second portion 1182 connecting the first portion 1181 to the circuit substrate 210 and laterally covered by the encapsulant 310. The encapsulant 310 may provide protection against moisture permeation. In some embodiments, the encapsulant 310 is optically opaque to provide the optical isolation of the sensor die 110.

Still referring to FIG. 1, the circuit substrate 210 may include a first side 210a, a second side 210b opposite to the first side 210a, and a sidewall 210c connected to the first side 210a and the second side 210b. The conductive terminals 118 and the encapsulant 310 may be disposed on the first side 210a of the circuit substrate 210. For example, the circuit substrate 210 includes one or more dielectric layer(s) 211 and conductive patterns 212 embedded in the dielectric layer 211, where the conductive patterns 212 are electrically connected to the conductive terminals 118. The circuit substrate 210 may include external terminals 214 formed at the second side 210b and electrically coupled to the conductive patterns 212. In alternative embodiments, more or fewer elements may be adapted to form the sensor package 10. It should be noted that the configuration of the sensor package 10 in FIG. 1 merely serves as an exemplary illustration and the disclosure is not limited thereto.

FIGS. 2A-2H are schematic cross-sectional views illustrating a sensor package at various steps of fabrication, in accordance with some embodiments. For example, the processes shown in FIGS. 2A-2F are performed in wafer level, and the processes shown in FIGS. 2G-2H are performed in chip level. Like reference numerals refer to corresponding parts throughout the several views of the drawings.

Referring to FIG. 2A, a semiconductor wafer 1110 (e.g., a silicon wafer or the like) including a plurality of die regions 1110R may be provided. For example, the pixels 112 are formed in the sensing area 110S, over the first side 111a, and within each die region 1110R. The contact pads 113 and the dielectric layer 114 may be formed over the first side 111a of the semiconductor wafer 1110, where the contact pads 113 are distributed outside the sensing area 110S and within each die region 1110R. In some embodiments, a temporary carrier 24 provided with a temporary dam 22 is attached to the semiconductor wafer 1110 through a temporary adhesive layer 21. For example, the temporary carrier 24 is provided in a wafer form to cover the semiconductor wafer 1110. The material of the temporary carrier 24 may be selected to have a CTE (e.g., about 3.2 ppm/° C.) close to the CTE of the semiconductor wafer 1110, thereby reducing the CTE mismatch between the temporary carrier 24 and the semiconductor wafer 1110 during the subsequent processing. For example, the temporary carrier 24 is made of glass or the like. In some embodiments, the temporary carrier 24 is thick (or rigid) enough to withstand the stress caused by the subsequent processing performed on the semiconductor wafer 1110.

With continued reference to FIG. 2A, the temporary dam 22 may be disposed on the side of the temporary carrier 24 facing the semiconductor wafer 1110 to form a gap G1 between the temporary carrier 24 and the semiconductor wafer 1110. The configuration of the temporary dam 22 may ensure that the temporary carrier 24 is spatially and vertically separated from the pixels 112 in the sensing area 110S. The material of the temporary dam 22 may be or include any suitable polymer material, photoresist material, or the like. The temporary dam 22 may have a first side 22a attached to the temporary carrier 24 and a second side 22b opposite to the first side 22a and attached to the temporary adhesive layer 21. The material of the temporary adhesive layer 21 may be or include ultraviolet (UV) tape, glue, or any suitable adhesive material(s). The temporary adhesive layer 21 may temporarily attach the temporary dam 22 to the dielectric layer 114. For example, after adhering the temporary dam 22 with the temporary carrier 24 on top to the semiconductor wafer 1110, the temporary dam 22 and the underlying temporary adhesive layer 21 are arranged outside the sensing area 110S and may be disposed along the boundary of each die region 1110R.

Referring to FIG. 2B and FIG. 2A, one or more backside processes may be performed on the semiconductor wafer 1110 using the temporary carrier 24 as a support. For example, the structure shown in FIG. 2A is flipped upside-down, and then the semiconductor wafer 1110 may be etched from the backside to form the semiconductor substrate 111 including the through holes 111T, where at least a portion of the contact pads 113 may be exposed by the through holes 111T. In some embodiments, after the backside processing, the second side 111b of the semiconductor substrate 111 having the irregular cross-sectional profile is formed. The outer sidewall 111c of the semiconductor substrate 111 may be slanted according to some embodiments. Next, the oxide layer 1161, the buffer layer 1162, and the RDL 115 may be sequentially formed on the second side 111b and the outer sidewall 111c of the semiconductor substrate 111. For example, the oxide layer 1161 and the buffer layer 1162 are made of different materials, where the oxide layer 1161 may include silicon oxide and/or the like. The RDL 115 may include one or more conductive material(s) such as Ti, Cu, Ni, Au, alloy, and/or the like, and may be in direct contact with the portion of the contact pads 113 exposed by the through holes 111T.

With continued reference to FIG. 2B, the insulating layer 117 may then be formed on over the temporary carrier 24 to cover each of the die regions 1110R. For example, the insulating layer 117 includes one or more passivation material(s), solder mask material(s), or any suitable insulating material, and may be formed using any suitable deposition process. During (or after) forming the insulating layer 117, the blank areas 1171 may be formed over the contact pads 113 and within the through holes 111T. For example, no insulating material is formed in the blank areas 1171. By configuring the blank area 1171, the insulating layer 117 may be spatially separated from the contact pads 113 and the portion of the RDL 115 connected to the contact pads 113, and thus the contact pads 113 and the portion of the RDL 115 may not be affected by thermal expansion and contraction of the insulating layer 117 during the subsequent processing and operation of the resulting sensor package.

As shown in FIG. 2B, after the formation of the insulating layer 117, the insulating layer 117 may have the non-planar surface 117s, where the first section 117s1 of the non-planar surface 117s covers the thicker portion (or the central portion) of the semiconductor substrate 111, and the second section 117s2 of the non-planar surface 117s covers the thinner portion (or the peripheral portion) of the semiconductor substrate 111 and the through holes 111T. The first section 117s1 may be flatter than the second section 117s2. In some embodiments, the second section 117s2 has a concave curved profile as shown in FIG. 2B. Depending on the material and the deposition process of the insulating layer 117, the insulating layer 117 may have a different cross-sectional profile than shown.

Referring to FIG. 2C and FIG. 2B, the temporary carrier 24 along with the temporary dam 22 may be de-bonded to expose the sensing area 110S. For example, the structure of FIG. 2B is flipped upside-down for the de-bonding process. In some embodiments, the radiation (not shown) is shined onto the temporary adhesive layer 21 and the temporary adhesive layer 21 may decompose, thereby removing the temporary carrier 24 and the temporary dam 22 from the dielectric layer 114. In some embodiments, a suitable solvent is used to dissolve the temporary adhesive layer 21 so as to remove the temporary carrier 24 and the temporary dam 22 from the dielectric layer 114. A cleaning process is optionally performed on the dielectric layer 114 to clean the residues of the temporary adhesive layer 21 (if any) after the de-bonding process.

Referring to FIG. 2D and FIG. 2C, the dielectric dam 122 may be formed on the dielectric layer 114 and may encircle the boundary of each die region 1110R. The dielectric dam 122 may be or include an epoxy, a solder mask, or any suitable polymer material(s), and may be formed by suitable deposition process such as dispensing, 3D printing, dry film attachment, or the like. In some embodiments, the dielectric dam 122 includes a material which is optically opaque to provide the optical isolation of the sensing area 110S. The dielectric dam 122 may have the height 122H to eliminate pixel defects such as blemish defects. For example, the height 122H of the dielectric dam 122 is greater than 40 microns, such as about 80 microns or higher than 80 microns. However, any suitable value of the height 122H may be used depending on product and process requirements.

Referring to FIG. 2E and FIG. 2D, the cover layer 124 may be disposed on the dielectric dam 122 and cover the die regions 1110R, and a cavity C1 is formed among the cover layer 124, the dielectric dam 122, and the dielectric layer 114. The height of the cavity C1 may depend on the height 122H (labeled in FIG. 2D) of the dielectric dam 122. For example, the cover layer 124 is provided in a wafer form. In some embodiments, the dielectric dam 122 provides sufficient adhesion property, and the second side 124b of the cover layer 124 is adhered to the dielectric dam 122. In some embodiments, the dielectric dam 122 is formed on the cover layer 124 and then is disposed on dielectric dam 122 and covers the die regions 1110R. In some embodiments, the cover layer 124 is a transparent cover such as a glass cover. The cover layer 124 may include any suitable material(s) depending on the optical requirements and the warpage performance (e.g., considering the CTE compatibility) of the resulting sensor package. The material of the cover layer 124 may be different from that of the temporary carrier 24 described in FIG. 2A. Since the attachment of the cover layer 124 is performed after the formation of the insulating layer 117, a wider range of materials may be available to be used as the cover layer 124 without concerns for the CTE mismatch among the cover layer 124, the insulating layer 117, and the semiconductor substrate 111. For example, the material of the cover layer 124 has a higher CTE than the CTE of the semiconductor substrate 111. The cover layer 124 may be or include an infrared-cut filter (IRCF), an infrared-pass filter (IRPF), or any suitable type of cover depending on product and optical requirements. In addition, since the attachment of the cover layer 124 is performed after processing on the semiconductor wafer 1110, the defect features (e.g., scratches, residues, glass defects, etc.) of the cover layer formed during the processing may be eliminated, or the cover layer having defects may not be used and only defect-free cover layer 124 may be used, thereby improving production yield.

With continued reference to FIG. 2E, the light-shielding layer 126 may be disposed at the first side 124a of the cover layer 124. The light-shielding layer 126 may be formed after attaching the cover layer 124 to the dielectric dam 122 or may be provided on the cover layer 124 before attaching the cover layer 124 to the dielectric dam 122. The light-shielding layer 126 may be disposed at the locations corresponding to the locations of the dielectric dam 122 on the cover layer 124. For example, the light-shielding layer 126 is arranged along the boundary of each of the die regions 1110R after the attachment of the cover layer 124. The light-shielding layer 126 may be formed using a variety of optically opaque materials, such as a metal layer, a black photo-resist, a dry film, and/or the like. The light-shielding layer 126 may be a single layer or include a multi-layered structure formed of different materials. In some embodiments, the light-shielding layer 126 and the dielectric dam 122 are formed of the same material. Alternatively, the light-shielding layer 126 and the dielectric dam 122 are made of different materials depending on product and optical requirements.

Referring to FIGS. 2F-2G and FIG. 2E, the conductive terminals 118 may be formed through the insulating layer 117 and in contact with the RDL 115. For example, openings (not labeled) are formed in the insulating layer 117 and within the area corresponding to the first section 117s1 of the non-planar surface 117s, where at least a portion of the RDL 115 may be exposed by the openings of the insulating layer 117. In some embodiments, the conductive terminals 118 are formed by reflowing solder material in the openings of the insulating layer 117. However, the conductive terminals 118 may include any suitable materials and shapes.

With continued reference to FIGS. 2F-2G, after forming the conductive terminals 118, a singulation process SP1 may be performed on the scribe lanes to dice along the boundary of the die regions 1110R. For example, the light-shielding layer 126, the cover layer 124, and the insulating layer 117 are cut during the singulation process, and a plurality of sensor dies 110 covered by the insulating layer 117 may then be formed, where the dielectric dam 122, the cover layer 124, and the light-shielding layer 126 disposed over the respective sensor die 110 and the insulating layer 117. For example, the sidewall 117c of the insulating layer 117 and the sidewall 124c of the cover layer 124 are substantially coplanar with each other. The outer sidewall 122c of the dielectric dam 122 may be laterally offset from the sidewall 124c of the cover layer 124. The sidewall 126c of the light-shielding layer 126 may (or may not) be substantially coplanar with the sidewall 124c of the cover layer 124.

With continued reference to FIG. 2G, the respective sensor die 110 may be disposed on and coupled to the circuit substrate 210. For example, the conductive terminals 118 are in physical and electrical contact with the conductive patterns 212 (e.g., contact pads) exposed at the first side 210a. A reflow process may be performed to couple the conductive terminals 118 to the conductive patterns 212 at the first side 210a. In some embodiments, the circuit substrate 210 is a redistribution structure formed by alternately stacking layers of dielectrics and conductive patterns. The numbers of the dielectric layer 211 and conductive patterns 212 may depend on the circuit design and construe no limitation in the disclosure. In some embodiments, since the circuit substrate 210 connected to the sensor die 110 reroutes the electrical signal of the sensor die 110 and may expand wider than the size of the sensor die 110, the circuitry of the circuit substrate 210 may be viewed as a fan-out redistribution circuitry.

Referring to FIG. 2H and FIG. 2G, the encapsulant 310 may be formed on the first side 210a to cover laterally the insulating layer 117, the dielectric dam 122, the cover layer 124, and the light-shielding layer 126. The encapsulant 310 may further extend into the gap between the insulating layer 117 and the first side 210a of the circuit substrate 210 to surround the conductive terminals 118. In some embodiments, the encapsulant 310 is formed of one or more moldable material(s) by a molding process. However, the encapsulant 310 may be formed of any suitable encapsulating materials by using any suitable deposition process. In some embodiments, the encapsulant 310 and the insulating layer 117 are formed of different materials. For example, the encapsulant 310 includes fillers formed in an epoxy base material, while the insulating layer 117 is free of fillers. Alternatively, the encapsulant 310 and the insulating layer are made of the same material.

With continued reference to FIG. 2H, after the formation of the encapsulant 310, the external terminals 214 are formed on the conductive patterns 212 (e.g., contact pads) exposed at the second side 210b. In some embodiments, the external terminals 214 are solder balls formed by reflowing solder materials formed in the openings of the dielectric layer 211 at the second side 210b and on the conductive patterns 212. For example, the external terminals 214 are ball grid array (BGA) and have a size greater than that of the conductive terminals 118. However, the external terminals 214 may include any suitable terminal forms and shapes. The circuit substrate 210 may fan out from the sensor die 110, and also the circuit substrate 210 may have a flexible layout design according to product and circuit requirements. The performance of the board-level reliability may also be improved. After forming the external terminals 214, a singulation process may be performed to dice the encapsulant 310 and the dielectric layer 211 of the circuit substrate 210. For example, the sidewall 210c of the circuit substrate 210 is substantially coplanar with the sidewall 310c of the encapsulant 310. Up to here, the fabrication of the sensor package 10 is substantially complete.

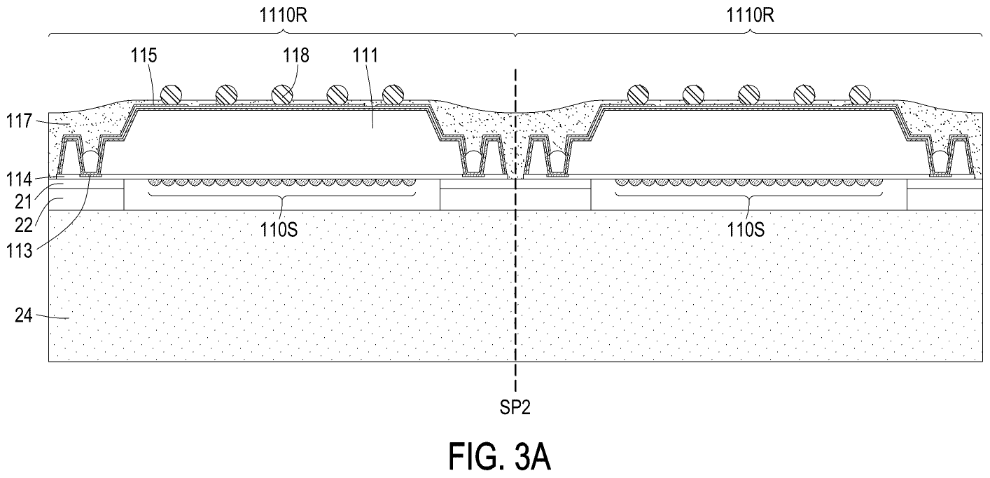

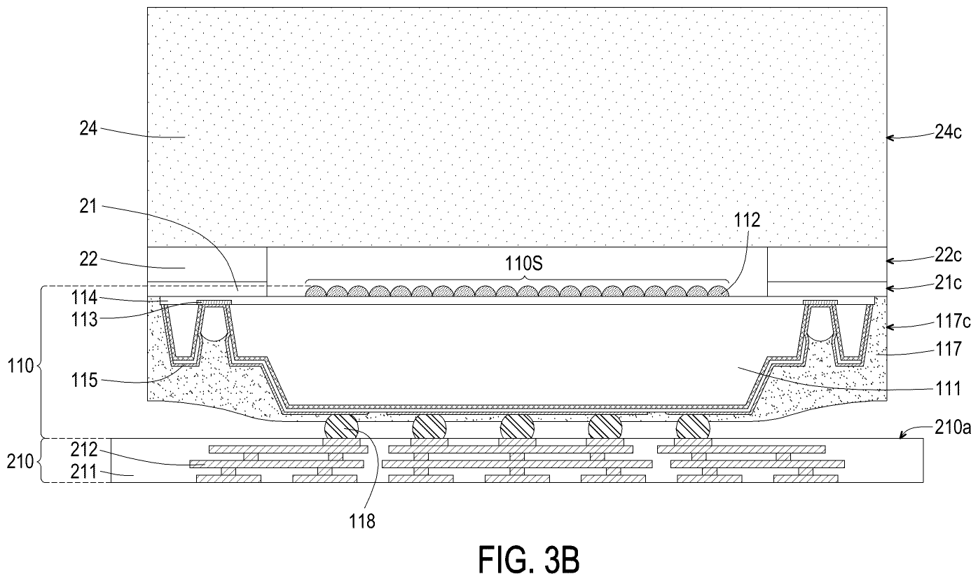

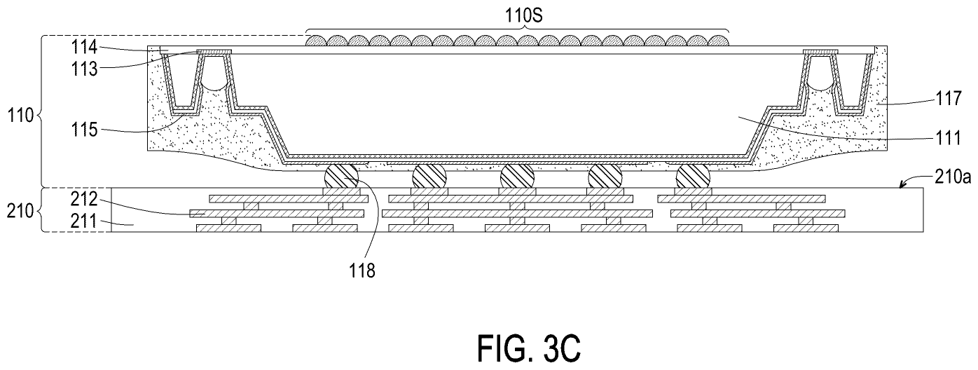

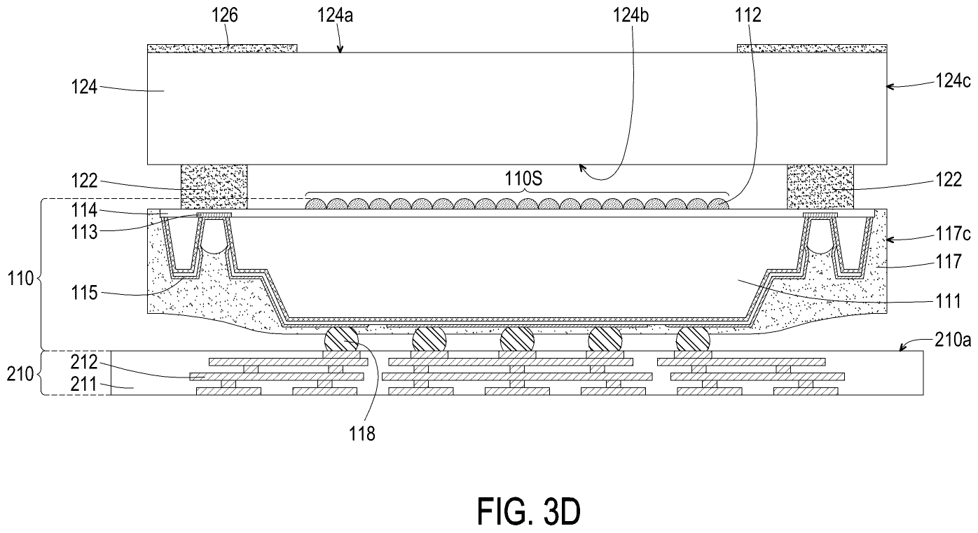

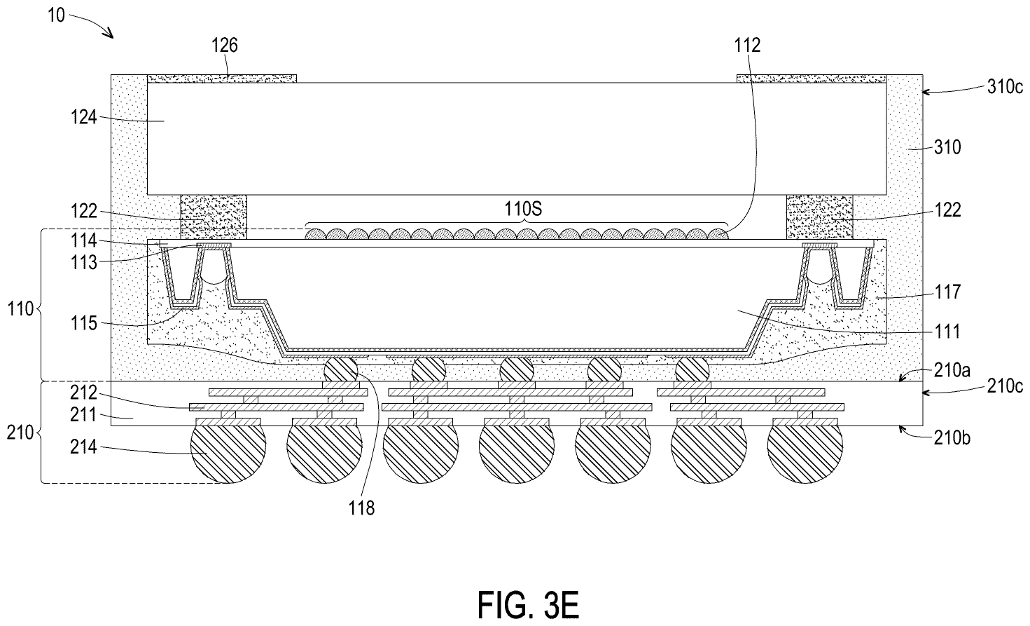

FIGS. 3A-3E are schematic cross-sectional views illustrating a sensor package at various steps of fabrication, in accordance with some embodiments. For example, the process shown in FIG. 3A is performed in wafer level, and the processes shown in FIGS. 3B-3E are performed in chip level. Like reference numerals refer to corresponding parts throughout the several views of the drawings.

Referring to FIGS. 3A-3B and FIG. 2B, after the formation of the insulating layer 117 as described in FIG. 2B, the conductive terminals 118 may be formed in the openings of the insulating layer 117 and in contact with the RDL 115. After forming the conductive terminals 118, a singulation process SP2 may be performed to dice along the boundary of the die regions 1110R. For example, the insulating layer 117, the temporary adhesive layer 21, the temporary dam 22, and the temporary carrier 24 are cut, and a plurality of sensor dies 110 may be formed, where the respective sensor die 110 is held by the temporary carrier 24 with the temporary adhesive layer 21 and the temporary dam 22 interposed therebetween. In some embodiments, after the singulation process SP2, the sidewall 24c of temporary carrier 24, the sidewall 22c of the temporary dam 22, the sidewall 21c of the temporary adhesive layer 21, and the sidewall 117c of the insulating layer 117 are substantially coplanar with one another. After the singulation process SP2, the respective sensor die 110 held by the temporary carrier 24 may be disposed on and coupled to the first side 210a of the circuit substrate 210. For example, the conductive terminals 118 are in physical and electrical contact with the conductive patterns 212 (e.g., contact pads) exposed at the first side 210a.

Referring to FIG. 3C and FIG. 3B, after coupling the conductive terminals 118 to the circuit substrate 210, the temporary carrier 24 and the temporary dam 22 may be de-bonded from the sensor die 110 by releasing the temporary adhesive layer 21. The de-bonding process of the temporary carrier 24, the temporary dam 22, and the temporary adhesive layer 21 may be similar to the process described in FIG. 2C, and thus the details of the de-bonding process are not repeated for simplicity. After the de-bonding process, the sensing area 110S of the sensor die 110 may be exposed.

Referring to FIG. 3D and FIG. 3C and FIGS. 2D-2E, the dielectric dam 122 may be formed on the dielectric layer 114 and surround the boundary of the sensing area 110S. Next, the cover layer 124 may be disposed on the dielectric dam 122 and cover the sensor die 110. The light-shielding layer 126 may be disposed at the first side 124a of the cover layer 124, while the dielectric dam 122 may be disposed at the second side 124b of the cover layer 124. The formation/attachment of the dielectric dam 122, the cover layer 124, and the light-shielding layer 126 are similar to the processes described in FIGS. 2D-2E, and thus the details thereof are not repeated for simplicity. Since the cover layer 124 is attached to the sensor die 110 after the singulation of the insulating layer 117, the sidewall 124c of the cover layer 124 may be substantially coplanar with the sidewall 117c of the insulating layer 117 or may be laterally offset from the sidewall 117c of the insulating layer 117.

Referring to FIG. 3E and FIG. 3D and FIG. 2H, the encapsulant 310 may be formed on the first side 210a to laterally cover the insulating layer 117, the dielectric dam 122, the cover layer 124, and the light-shielding layer 126. The encapsulant 310 may extend into the gap between the insulating layer 117 and the circuit substrate 210 to surround the conductive terminals 118. Next, the external terminals 214 may be formed on the conductive patterns 212 (e.g., contact pads) exposed at the second side 210b. A singulation process may then be performed to dice the encapsulant 310 and the dielectric layer 211 of the circuit substrate 210. The formation of the encapsulant 310 and the external terminals 214 and the singulation may be similar to the processes described in FIG. 2H, and thus the details thereof are not repeated for simplicity. Up to here, the fabrication of the sensor package 10 is substantially complete.

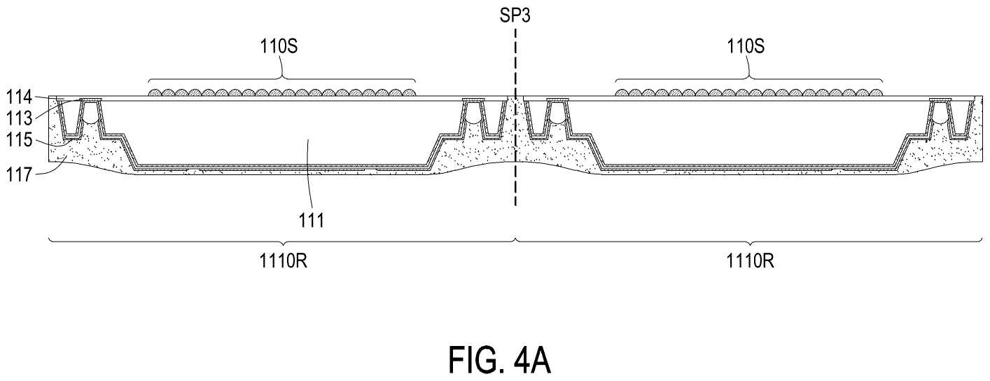

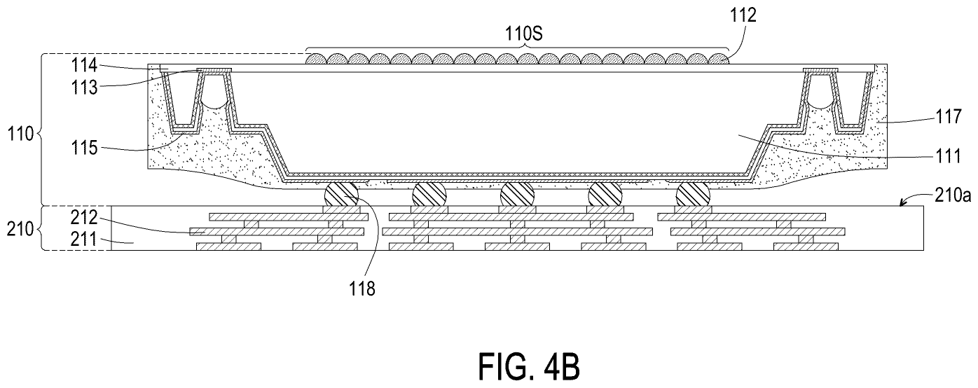

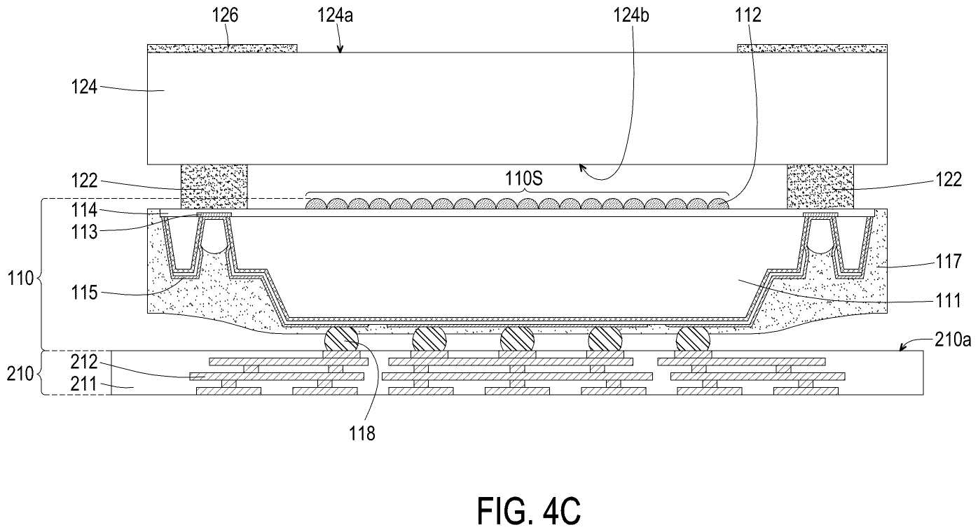

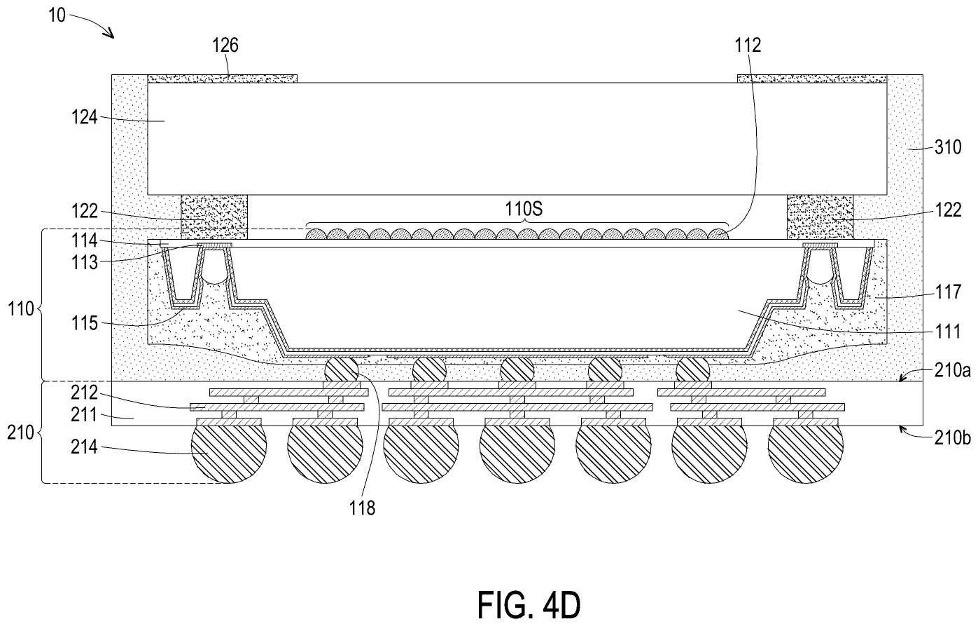

FIGS. 4A-4D are schematic cross-sectional views illustrating a sensor package at various steps of fabrication, in accordance with some embodiments. For example, the process shown in FIG. 4A is performed in wafer level, and the processes shown in FIGS. 4B-4D are performed in chip level. Like reference numerals refer to corresponding parts throughout the several views of the drawings.

Referring to FIGS. 4A-4B and FIG. 2C, the structure shown in FIG. 4A is similar to the structure shown in FIG. 2C. The formation of the structure in FIG. 4A may refer to the processes described in FIGS. 2A-2C, and thus the details thereof are not repeated for simplicity. Next, a singulation process SP3 may be performed to dice along the boundary of the die regions 1110R. For example, the insulating layer 117 is cut during the singulation process SP3. The singulated structure may then be disposed on and coupled to the conductive patterns 212 of the circuit substrate 210 through the conductive terminals 118, as shown in FIG. 4B.

Referring to FIG. 4C and FIG. 4B and FIGS. 2D-2E, the dielectric dam 122 may be formed on the dielectric layer 114 and surround the boundary of the sensing area 110S. Next, the cover layer 124 may be disposed on the dielectric dam 122 and cover the sensor die 110. The light-shielding layer 126 may be disposed at the first side 124a of the cover layer 124, while the dielectric dam 122 may be disposed at the second side 124b of the cover layer 124. The formation/attachment of the dielectric dam 122, the cover layer 124, and the light-shielding layer 126 are similar to the processes described in FIGS. 2D-2E or FIG. 3D, and thus the details thereof are not repeated for simplicity.

Referring to FIG. 4D and FIG. 4C and FIG. 2H, the encapsulant 310 may be formed on the first side 210a to cover laterally the insulating layer 117, the dielectric dam 122, the cover layer 124, and the light-shielding layer 126. The encapsulant 310 may extend into the gap between the insulating layer 117 and the circuit substrate 210 to surround the conductive terminals 118. Next, the external terminals 214 may be formed on the second side 210b of the circuit substrate 210. A singulation process may then be performed to dice the encapsulant 310 and the dielectric layer 211 of the circuit substrate 210. The formation of the encapsulant 310 and the external terminals 214 and the singulation process may be similar to the processes described in FIG. 2H or FIG. 3E, and thus the details thereof are not repeated for simplicity. Up to here, the fabrication of the sensor package 10 is substantially complete.

Based on the above, the sensor package includes the cover layer which can be selected from a wider range of materials without concerns for the CTE mismatch among the cover layer, the insulating layer, and the semiconductor substrate. The CTE mismatch may cause reliability concerns and the issues associated with the modulation transfer function (MTF). By attaching the cover layer to the sensor die after covering the sensor die with the insulating layer, the properties (e.g., the material, the thickness, the optical performance, etc.) of the cover layer may not be constrained due to the fabrication of the sensor die and the deposition of the insulating layer. In addition, only defect-free cover layer may be used to form the sensor package, thereby improving production yield. Moreover, the dielectric dam may have a sufficient height to eliminate blemish defects. The sensor package may include the encapsulant covering the cover layer, the dielectric dam, the insulating layer, and the conductive terminals so as to provide a better protection and resist an impact by an external force, thereby improving the reliability of the sensor package and eliminating the delamination issues of the dielectric dam for some products which have a larger size of the sensor die.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A sensor package, comprising:
a sensor die comprising a first side, a second side opposite to the first side, a sensing area at the first side, a plurality of conductive terminals at the second side;
an insulating layer covering the second side of the sensor die and exposing the first side of the sensor die;
a cover layer disposed above the first side of the sensor die and covering the sensing area;
a dielectric dam interposed between the cover layer and the sensor die and disposed outside the sensing area;
a circuit substrate coupled to the sensor die through the plurality of conductive terminals; and
an encapsulant laterally covering the cover layer, the dielectric dam, and the insulating layer, the encapsulant extending into a gap between the circuit substrate and the insulating layer to surround the plurality of conductive terminals.

2. The sensor package of claim 1, wherein each of the plurality of conductive terminals comprises:
a first portion inserted into the insulating layer; and
a second portion connecting the first portion to the circuit substrate and laterally covered by the encapsulant.

3. The sensor package of claim 1, wherein an outer sidewall of the cover layer is substantially coplanar with an outer sidewall of the insulating layer, and an outer sidewall of the dielectric dam is laterally offset from the outer sidewall of the cover layer.

4. The sensor package of claim 1, further comprising:
a light-shielding layer disposed at a side of the cover layer opposite to the dielectric dam, wherein the encapsulant layer laterally covers the light-shielding layer.

5. The sensor package of claim 1, wherein the sensor die comprises a semiconductor substrate on which pixels are disposed in the sensing area, and a coefficient of thermal expansion of the cover layer is greater than that of the semiconductor substrate.

6. The sensor package of claim 1, wherein an outer sidewall of the encapsulant is substantially coplanar with an outer sidewall of the circuit substrate.

7. A manufacturing method of a sensor package, comprising:
covering a sensor die with an insulating layer, wherein the sensor die comprises a first side exposed by the insulating layer, a second side opposite to the first side, and a sensing area at the first side;
disposing a cover layer over the first side of the sensor die with a dielectric dam interposed between the sensor die and the cover layer, wherein the dielectric dam is formed outside the sensing area;
coupling the sensor die to a circuit substrate through a plurality of conductive terminals formed at the second side of the sensor die; and
forming an encapsulant on the circuit substrate to cover the cover layer, the dielectric dam, and the sensor die, wherein the encapsulant extends into a gap between the circuit substrate and the insulating layer to surround the plurality of conductive terminals.

8. The manufacturing method of claim 7, further comprising:
forming the plurality of conductive terminals at the second side of the sensor die after disposing the cover layer over the sensor die, wherein after forming the encapsulant, each of the plurality of conductive terminals comprises a first portion inserted into the insulating layer and a second portion connecting the first portion to the circuit substrate and laterally covered by the encapsulant.

9. The manufacturing method of claim 7, further comprising:
forming the plurality of conductive terminals at the second side of the sensor die before disposing the cover layer over the sensor die, wherein after forming the encapsulant, each of the plurality of conductive terminals comprises a first portion inserted into the insulating layer and a second portion connecting the first portion to the circuit substrate and laterally covered by the encapsulant.

10. The manufacturing method of claim 7, wherein covering the sensor die with the insulating layer and disposing the cover layer over the first side of the sensor die are performed in wafer level, the manufacturing method further comprises:
performing a singulation process to dice the cover layer and the insulating layer before coupling the sensor die to the circuit substrate.

11. The manufacturing method of claim 7, wherein covering the sensor die with the insulating layer is performed in wafer level, the manufacturing method further comprises:
performing a singulation process to dice the insulating layer before disposing the cover layer over the first side of the sensor die.

12. The manufacturing method of claim 7, further comprising:
forming pixels on a semiconductor wafer to define the sensing area;
adhering a temporary carrier and a temporary dam to the semiconductor wafer through a temporary adhesive layer, wherein the temporary dam is interposed between the temporary carrier and the temporary adhesive layer, and the temporary dam and the temporary adhesive layer are disposed outside the sensing area; and
forming the sensor die by processing the semiconductor wafer, wherein when forming the sensor die, the temporary carrier serves as a support.

13. The manufacturing method of claim 12, wherein the temporary carrier is provided in a wafer form.

14. The manufacturing method of claim 13, further comprising:
performing a singulation process to dice the temporary carrier, the temporary dam, the temporary adhesive layer, and the insulating layer before coupling the sensor die to the circuit substrate.

15. The manufacturing method of claim 12, further comprising:
de-bonding the temporary carrier and the temporary dam by releasing the temporary adhesive layer from the sensor die to expose the sensing area after covering the sensor die with the insulating layer.

16. The manufacturing method of claim 12, further comprising:
de-bonding the temporary carrier and the temporary dam by releasing the temporary adhesive layer from the sensor die to expose the sensing area after forming the plurality of conductive terminals and before coupling the sensor die to the circuit substrate.

17. The manufacturing method of claim 12, wherein a difference of coefficients of thermal expansion of the temporary carrier and the semiconductor wafer is less than a difference of coefficients of thermal expansion of the cover layer and the semiconductor wafer.

18. The manufacturing method of claim 7, wherein the cover layer is provided with a light-shielding layer formed on a first side opposite to a second side connected to the dielectric dam, and after forming the encapsulant, the light-shielding layer is laterally covered by the encapsulant.

19. The manufacturing method of claim 7, further comprising:
performing a singulation process to dice the encapsulant and the circuit substrate, wherein sidewalls of the encapsulant and the circuit substrate are substantially coplanar.

20. A sensor package, comprising:
a sensor die comprising a semiconductor substrate, a sensing area disposed on a front side of the semiconductor substrate, a redistribution layer conformally overlying a backside of the semiconductor substrate, and a plurality of conductive terminals connected to the redistribution layer, wherein the backside of the semiconductor substrate comprises an irregular cross-sectional profile formed by using a temporary carrier as a support;
an insulating layer covering the redistribution layer and exposing the sensing area, wherein the insulating layer is formed by using the temporary carrier as the support;
a cover layer disposed above the sensing area of the sensor die, wherein a difference of coefficients of thermal expansion of the temporary carrier and the semiconductor substrate is less than a difference of coefficients of thermal expansion of the cover layer and the semiconductor substrate;
a dielectric dam interposed between the cover layer and the sensor die and disposed outside the sensing area;
a circuit substrate coupled to the sensor die through the plurality of conductive terminals; and
an encapsulant laterally covering the cover layer, the dielectric dam, and the insulating layer, wherein each of the plurality of conductive terminals comprises a first portion inserted into the insulating layer and a second portion connecting the first portion to the circuit substrate and laterally covered by the encapsulant.
